(19) United States
(12) Patent Application Publication
(10) Pub. No.: US 2008/0266766 A1
(43) Pub. Date: Oct. 30, 2008

(54) SMUDGE REMOVAL FROM ELECTRONIC DEVICE DISPLAYS

(75) Inventors: John J. D'Urso, Chandler, AZ (US); Pawitter S. Mangat, Gilbert, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/741,463

(22) Filed: Apr. 27, 2007

(51) Int. Cl. H05K 5/00; B08B 1/02; B08B 7/04

(52) U.S. Cl. 361/681; 134/1; 134/15

(57) ABSTRACT

An apparatus and method is provided for removing smudges (624) including oils and dust from portable electronic displays (110, 150, 200, 300, 334). The apparatus comprises a display device (600, 700, 800, 900) positioned within a housing (102, 104), having a surface (601) viewable through an opening in the housing (102, 104) and a susceptibility to receiving contaminants (624). Gradients are formed on the display device (600, 700, 800, 900) for providing a differential surface tension that causes the smudges (624) to migrate across the viewable surface of the display device (600, 700, 800, 900). The gradients may be, for example, thermal (604, 605), electrical (702, 708), optical (804), or surface wettability (904).

### FIELD OF THE INVENTION

The present invention generally relates to portable electronic device displays and more particularly to an apparatus and method for removing smudges including oils and dust therefrom.

### BACKGROUND OF THE INVENTION

In many portable electronic devices, such as mobile communication devices, displays present information to a user. For example, polymer-dispersed liquid crystal (PDLC) display technology can display video and text information. These optical displays, especially touch panel displays, typically comprise a transparent or a high gloss reflective surface thermoplastic or glass layer. While these transparent layers have excellent transparency and are physically strong, they suffer both aesthetic and functional degradation due to the build up of oils and other contaminants during use. This is particularly true for the display components of products which receive significant handling, such as personal data assistants (PDAs) and cell phones. For these displays, any type of fouling is especially undesirable as it tends to be very noticeable to the user and can result in a less than satisfactory viewing experience.

While screen protectors are available for many of these products, they do not offer an optimal solution. Most are based on anti-fouling coatings that reduce but do not eliminate smudges. Furthermore, the screen protectors often become scratched or otherwise degraded, necessitating that the consumer periodically replace them. For example, see U.S. Pat. No. 6,660,388 and European patent application EP 1 712 531 A2.

Accordingly, it is desirable to provide an apparatus and method for removing smudges including oils and dust from portable electronic devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

An apparatus and method are provided for removing smudges including oils and dust from portable electronic devices. The electronic device comprises a display device positioned within a housing and a transparent cover having a surface viewable outside of the housing and susceptible to receiving a smudge. The transparent cover includes gradients that cause the smudge to migrate across the surface; and electronic circuitry to present information through the transparent cover. The gradients comprises one of thermal, electrical, optical, or wettability gradients, for example.

### BRIEF DESCRIPTION OF THE DRAWINGS

The present invention will hereinafter be described in conjunction with the following drawing figures, wherein like numerals denote like elements, and

FIG. 1 is a front view of a mobile communication device having a touch screen in accordance with an exemplary embodiment;

FIG. 2 is a partial cross-section of a conventional touch screen taken along line 2-2 of FIG. 1;

FIG. 3 is a cross sectional diagram of a conventional TN/PDLC touch screen taken along line 3-3 of FIG. 1;

FIG. 4 is a timing diagram for a display driver and a capacitive sensor operating the touch screen of FIG. 2 in a conventional manner;

FIG. 5 is a block diagram of a mobile communications device in accordance with an exemplary embodiment;

FIG. 6 is a partial cross-section of a display screen in accordance with a first exemplary embodiment taken along the line 6-6 of FIG. 7;

FIG. 7 is a partial view of the display screen of FIG. 6;

FIG. 8 is a partial cross-section of the display screen of FIG. 5 illustrating smudge movement in relation to the smudge shown in FIG. 5;

FIG. 9 is a partial top view of a display screen in accordance with a second exemplary embodiment;

FIG. 10 is a partial cross-section of the display screen taken along the line 10-10 of FIG. 9;

FIG. 11 is a partial cross-section of a display screen in accordance with a third exemplary embodiment; and

FIG. 12 is a partial cross-section of a display screen in accordance with a fourth exemplary embodiment.

FIG. 13 is a partial top view of a display screen in accordance with a fifth exemplary embodiment.

FIG. 14 is a partial cross-section of a display screen of FIG. 13.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

An integrated solution is disclosed that maintains the cleanliness of display surfaces without user intervention by the use of surface tension gradients, which may also be referred to as surface energy gradients, surface stress gradients, and others which generate what is commonly known as Marangoni flow. These surface tension gradients on the display cause smudges, such as droplets of oil, fatty acids, and other contaminants to migrate across the surface resulting in a clean viewing area. Basically, since an area of surface with a higher surface energy pulls more strongly on a smudge than an adjacent area of surface with a lower surface energy, the smudge moves, or migrates (interfacial convection), toward the area of higher surface energy. Generally, interfacial energy depends on both the temperature and chemical composition at the interface. More specifically, other forces are observed from a definition of the Marangoni number, a dimensionless number regarded as proportional to surface tension forces divided by viscous forces, given by the formula:

Mg=−(dσ/dT)(1/ηα)(L)(ΔT)

where

σ equals surface tension,

L equals characteristic length,

α equals thermal diffusivity,

η equals dynamic viscosity, and

ΔT equals temperature difference.

The gradients may be induced in any of several ways, including thermally, optically, electrically, or by a surface wettability gradient. Thermal gradients may be generated in a number of ways, most preferably by the inclusion of embedded microheaters formed under protective films to reduce the chance of damage during handling. The embedded microheaters could be embedded at edges of the display using physical vapor deposition or other thin film technologies. Transparent microheaters, e.g., indium tin oxide or very thin metallic or ceramic conductors, could be formed over the display.

Electrically induced gradients may be generated by patterning of thin, transparent, conductive islands across the surface of the display. As successive conductive islands are subjected to a voltage, an electric field moves across the transparent cover surface, thereby causing the contaminants to migrate across the surface.

Optically induced gradients may be generated by coating the surface of the display with a monolayer of specific materials which exhibit a photoresponse when illuminated. Such materials include azobenzene based phoreceptors such as azobenzene terminated calyx(4)resorcinarenes or other materials based on structures which can undergo photoisomerization such as rhodopsin or phytochrome.

Surface wettability gradients may be generated chemically or physically. They may be generated chemically by chemically functionalizing the surface of the display in an asymmetrical manner. For example, a single film for inducing a compositional gradient may be formed by combinatorial sputtering or by using diffusion controlled processes. Alternatively, a blanket film may be deposited on the display and then be lithographically patterned, e.g., masking and exposure to light, to form the gradients. They may be generated physically by forming the structure in an asymmetrical manner. For example, lithography or laser etching can be used to make the surface progressively rougher. These chemical and physical gradients are essentially passive, requiring no power during use.

In addition to each of the methods of forming interfacial surface tension gradients mentioned above, vibration devices, e.g., piezoelectric thin films, may be incorporated onto the display to increase the migration of the smudges across the display. While it would be preferred to cover the entire surface of the display with such films, the piezoelectric thin films may cover only a portion of the display, e.g., the edges or periphery of the display. Vibration or the induction of surface waves by surface acoustic wave filters or piezo elements which can actuate droplet motion with very small amplitudes can both aid in overcoming pinning energy barriers. Furthermore, the display cover material, thickness, tapering, and shape may be tailored to achieve optimum contaminant migration.

This approach may be particularly suitable to cell phones as haptic devices providing feedback to the user may also be connected to the display to cause migration of the contaminants. Therefore, rather than having to incorporate new elements which increase costs and occupy more space, an existing element may be adapted to serve a dual role.

As the contaminants build up in peripheral areas of the display, they can be hidden under a portion of the device housing, moved via capillary or self driven flow effects to areas less noticeable, or pooled into areas where removal can be accomplished by methods such as ejection by additional vibratory motion in a direction perpendicular to the screen or wiping by holster elements.

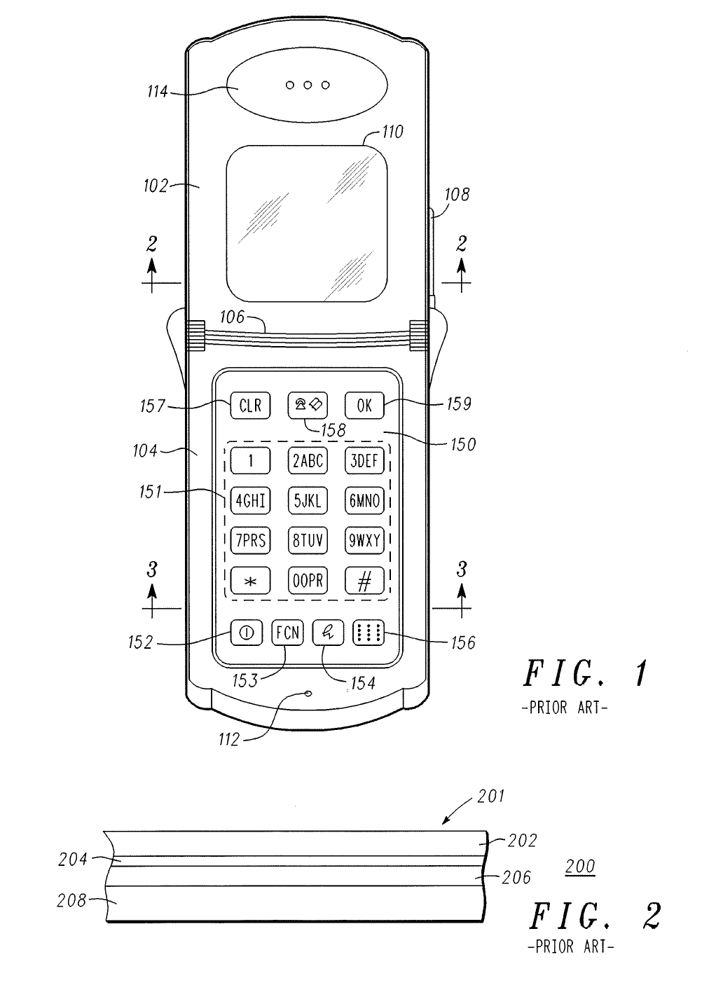

Although the apparatus and method described herein may be used with an exposed display surface for any type of electronic device, the exemplary embodiment as shown in FIG. 1 comprises a mobile communication device 100 implementing a touchscreen. While the electronic device shown is a mobile communication device 100, such as a flip-style cellular telephone, the touchscreen can also be implemented in cellular telephones with other housing styles, personal digital assistants, television remote controls, video cassette players, household appliances, automobile dashboards, billboards, point-of-sale displays, landline telephones, and other electronic devices.

The mobile communication device 100 has a first housing 102 and a second housing 104 movably connected by a hinge 106. The first housing 102 and the second housing 104 pivot between an open position and a closed position. An antenna 108 transmits and receives radio frequency (RF) signals for communicating with a complementary communication device such as a cellular base station. A display 110 positioned on the first housing 102 can be used for functions such as displaying names, telephone numbers, transmitted and received information, user interface commands, scrolled menus, and other information. A microphone 112 receives sound for transmission, and an audio speaker 114 transmits audio signals to a user.

A keyless input device 150 is carried by the second housing 104. The keyless input device 150 is implemented as a touchscreen with a display. A main image 151 represents a standard, twelve-key telephone keypad. Along the bottom of the keyless input device 150, images 152, 153, 154, 156 represent an on/off button, a function button, a handwriting recognition mode button, and a telephone mode button. Along the top of the keyless input device 150, images 157, 158, 159 represent a “clear” button, a phonebook mode button, and an “OK” button. Additional or different images, buttons or icons representing modes, and command buttons can be implemented using the keyless input device. Each image 151, 152, 153, 154, 156, 157, 158, 159 is a direct driven pixel, and this keyless input device uses a display with aligned optical shutter and backlight cells to selectively reveal one or more images and provide contrast for the revealed images in both low-light and bright-light conditions.

Referring to FIG. 2, a cross section of a conventional touchscreen 200 is depicted that is usable for either the display 110 or the keyless input device 150 with the cross-section, for example, being a portion of a view taken along line 2-2 of FIG. 1. The conventional display 200 is a stack with a user-viewable and user-accessible face 201 and multiple layers below the face 201, including a transparent cover 202, a thin transparent conductive coating 204, a substrate 206, and an imaging device 208. The transparent cover 202 provides an upper layer viewable to and touchable by a user and may provide some glare reduction. The transparent cover 202 also provides scratch and abrasion protection to the layers 204, 206, 208 contained below.

The substrate 206 protects the imaging device 208 and typically comprises plastic, e.g., polycarbonate or polyethylene terephthalate, or glass, but may comprise any type of material generally used in the industry. The thin transparent conductive coating 204 is formed over the substrate 206 and typically comprises a metal or an alloy such as indium tin oxide or a conductive polymer.

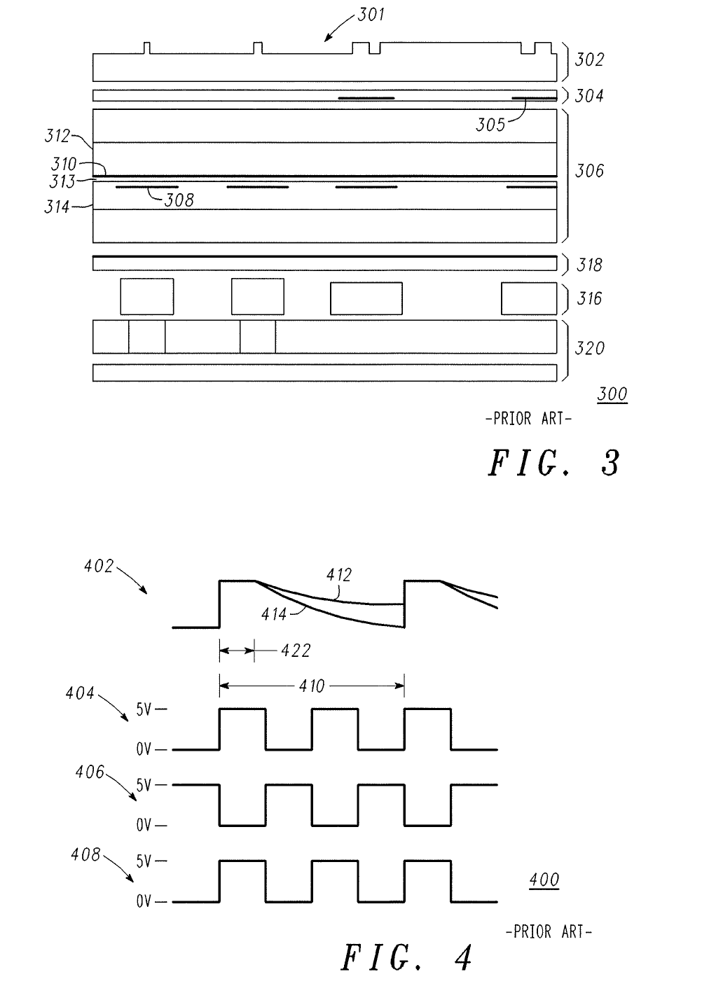

Referring to FIG. 3, a cross section of a conventional display 300 is depicted with aligned optical shutter and backlight cells and is usable for the display 110 of FIG. 1 with the cross-section being a portion of a view taken along line 3-3 of FIG. 1. The conventional display 300 is a stack with a user-viewable and user-accessible face 301 and multiple layers below the face 301, including a transparent cover 302 and a capacitive sensor layer 304 with an indium-tin oxide (ITO) electrode 305. The transparent cover 302 provides an upper layer viewable to and touchable by a user and may provide some glare reduction. The capacitive sensor layer 304 senses touchscreen inputs on the transparent cover 302 of the display 300. Beneath the capacitive sensor layer 304 is a twisted nematic (TN) stack layer 306 including a TN backplane electrode 310 and TN segment electrodes 308 between two substrates 312, 314 for providing the optical shutter operation of the display 300. The TN backplane electrode 310 and TN segment electrodes 308 are formed of indium-tin oxide (ITO) material to provide both transparency and electrical conductivity for operation of the TN stack. Also, while the TN backplane electrode 310 is depicted above the TN segment electrodes 308, a TN stack layer 306 having the TN backplane electrode 310 below the TN segment electrodes 308 would function similarly.

The TN stack layer 306 utilizes, for example, twisted nematic (TN) liquid crystal (TNLC) display technology employing TN optical shutter material in an optical shutter layer 313 and the TN segment electrodes 308 to provide optical shutter operation. While TNLC technology is described herein for the optical shuttering operation, the optical shutter layer 313, sandwiched between the TN backplane electrodes 310 and the TN polymer segment electrodes 308, can alternatively be made using nematic liquid crystal technology (such as twisted nematic or super twisted nematic liquid crystals), polymer-dispersed liquid crystal technology (PDLC), ferro-electric liquid crystal technology, electrically-controlled birefringent technology, optically-compensated bend mode technology, guest-host technology, and other types of light modulating techniques which use optical shutter material 313 such as TN polymer material, PDLC material, cholesteric material, or electro-optical material. The electric field created by the electrodes 308, 310 alter the light transmission properties of the TNLC optical shutter material 313, and the pattern of the TN segment electrode layer 308 defines pixels of the display. These pixels lay over the images 151, 152, 153, 154, 156, 157, 158, 159 shown in FIG. 1. In the absence of the electric field, the liquid crystal material and dichroic dye in the TNLC material 313 are randomly aligned and absorb most incident light. In the presence of the electric field, the liquid crystal material and dichroic dye align in the direction of the applied field and transmit substantial amounts of incident light. In this manner, a pixel of the TNLC cell can be switched from a relatively non-transparent state to a relatively transparent state. Each pixel can be independently controlled to be closed-shuttered or open-shuttered, depending on the application of an electric field, and the pixels act as “windows” with optical shutters that can be opened or closed, to reveal images underneath (e.g. images 151, 152, 153, 154, 156, 157, 158, 159).

Beneath the TN stack layer 306 is an electroluminescent (EL) stack layer 316 separated from the TN stack layer 306 by an ITO ground layer 318. The EL stack layer 316 includes a backplane and electrodes which provide backlight for operation of the display 300 in both ambient light and low light conditions by alternately applying a high voltage level, such as one hundred volts, to the backplane and electrode. The ITO ground layer 318 is coupled to ground and provides an ITO ground plane 318 for reducing the effect on the capacitive sensor layer 304 of any electrical noise generated by the operation of the EL stack layer 316 or other lower layers within the display 300. Beneath the EL stack layer 316 is a base layer 320 which may include one or more layers such as a force sensing switch layer and/or a flex base layer. The various layers 302, 304, 306, 318, 316 and 320 are adhered together by adhesive layers applied therebetween.

Conventional operation of the display 300 is illustrated in FIG. 4, wherein the charge 402 from the capacitive sensor layer 304, the voltage 404 of the TN backplane 310 and the voltages 406, 408 of first and second portions of the TN segment electrodes 308 are depicted. To perform capacitive sensing during a period 410, a charging voltage is provided to the ITO electrode 305 of the capacitive sensor layer 304 for a first portion 422 of the period 410. After the charging voltage is removed from the electrode 305, the charge 402 has two different decay profiles 412, 414 depending on whether a user's touch is detected on the display 300. In an electrically noisy environment, the signal-to-noise ratio (SNR) of the capacitive sensing (i.e., of the voltage of the detectable charge), where the charge is the multiple of the capacitance (determined from a distance of user's finger from the face 301) times the voltage thereof, is small, thereby complicating detection of touchscreen inputs. The ITO ground plane layer 318 provides some isolation between the high voltage EL backlight layer 316 and the low voltage TN stack layer 306, thereby increasing the SNR of the capacitive sensing.

During the same time period 410, the voltages 404, 406, 408 supplied to the TN backplane 310 and the TN segment electrodes 308 are switched between a positive voltage, typically about five volts, and zero volts. The voltage 406 of the portion of the TN segment electrodes 308 that are turned “on” to render corresponding portions of the display 300 over such portion of the TN segment electrodes 308 relatively transparent are switched opposite to the voltage 404 of the TN backplane 310 (i.e., when the voltage 304 of the TN backplane is high, the voltage 406 of the “on” portion of the TN segment electrodes 308 is low). Conversely, the voltage 408 of the portion of the TN segment electrodes 308 that are turned “off” optically shutter corresponding portions of the display 300 over such portion of the TN segment electrodes 308 because their voltage is switched in the same manner as the voltage 404 of the TN backplane 310. It can be seen from FIG. 4 that during period 410, the voltages 406, 408 supplied to the TN segment electrodes 308 and the TN backplane 310 are high approximately fifty percent of the time period 410.

Those skilled in the art will appreciate that other types of imaging devices 200, 300 may be utilized as exemplary embodiments, including, for example, transmissive, reflective or transflective liquid crystal displays, cathode ray tubes, micromirror arrays, and printed panels.

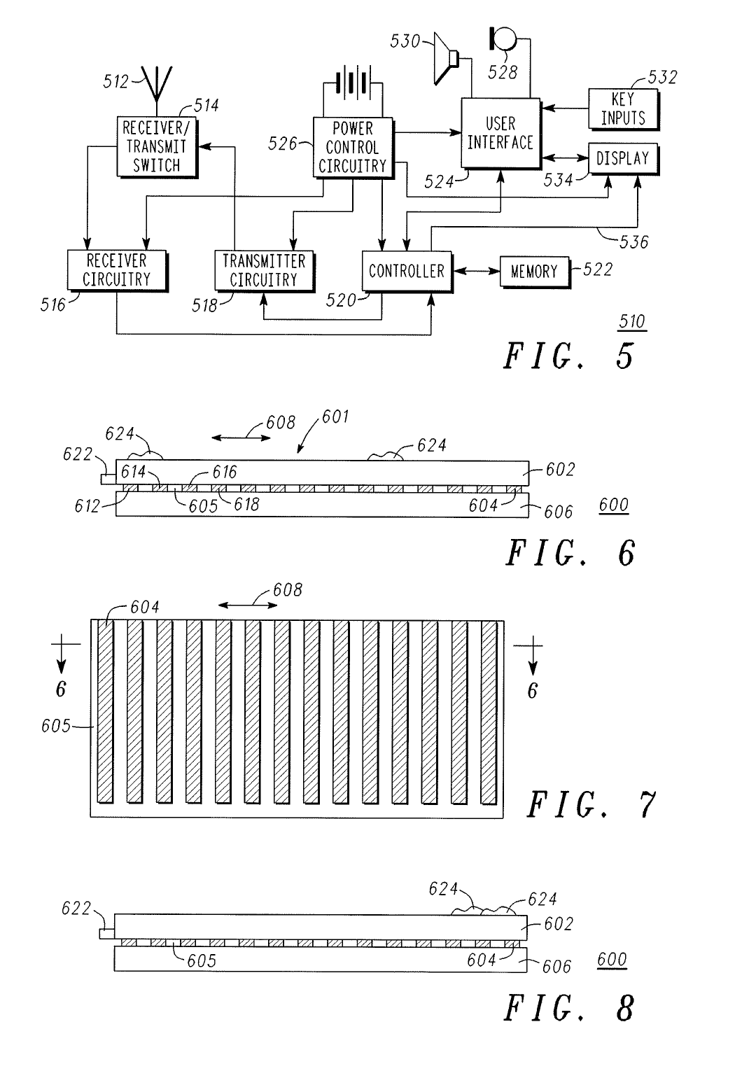

Referring to FIG. 5, a block diagram of a portable communication device 510 such as a cellular phone, in accordance with the preferred embodiment of the present invention is depicted. The portable electronic device 510 includes an antenna 512 for receiving and transmitting radio frequency (RF) signals, which may comprise any embodiments within the present invention, e.g., structures 100 and 200. A receive/transmit switch 514 selectively couples the antenna 512 to receiver circuitry 516 and transmitter circuitry 518 in a manner familiar to those skilled in the art. The receiver circuitry 516 demodulates and decodes the RF signals to derive information therefrom and is coupled to a controller 520 for providing the decoded information thereto for utilization thereby in accordance with the function(s) of the portable communication device 510. The controller 520 also provides information to the transmitter circuitry 518 for encoding and modulating information into RF signals for transmission from the antenna 512. As is well-known in the art, the controller 520 is typically coupled to a memory device 522 and a user interface 524 to perform the functions of the portable electronic device 510. Power control circuitry 526 is coupled to the components of the portable communication device 510, such as the controller 520, the receiver circuitry 516, the transmitter circuitry 518 and/or the user interface 524, to provide appropriate operational voltage and current to those components. The user interface 524 includes a microphone 528, a speaker 530 and one or more key inputs 532, including a keypad. The user interface 524 may also include a display 534 which could include touch screen inputs. The display 534 is coupled to the controller 520 by the conductor 536 for selective application of voltages in some of the exemplary embodiments described below.

The exemplary embodiments described herein may be fabricated using known lithographic processes as follows. The fabrication of integrated circuits, microelectronic devices, micro electro mechanical devices, microfluidic devices, and photonic devices, involves the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes. For example, a layer of photoresist material is applied onto a layer overlying a wafer substrate. A photomask (containing clear and opaque areas) is used to selectively expose this photoresist material by a form of radiation, such as ultraviolet light, electrons, or x-rays. Either the photoresist material exposed to the radiation, or that not exposed to the radiation, is removed by the application of a developer. An etch may then be applied to the layer not protected by the remaining resist, and when the resist is removed, the layer overlying the substrate is patterned. Alternatively, an additive process could also be used, e.g., building a structure using the photoresist as a template.

Referring to FIGS. 6 and 7 and in accordance with a first exemplary embodiment comprising thermal gradients, a display device 600 includes alternating strips of a plurality of conductive strips 604 and a dielectric material 605 formed over the substrate 606 using standard lithography techniques described above. A transparent cover 602 is formed over the alternating strips 604, 605. Cover 602 may be coated with an anti-smudge or other functional film. The substrate 606 and the transparent cover 602 comprise a transparent material, preferably glass or a plastic. The conductive strips 604 would also comprise a transparent material, preferably indium tin oxide. The transparent cover 602 may comprise a cover on any type of display, for example, the transparent covers 202 of FIG. 2 and the transparent cover 302 of FIG. 3. Each of the plurality of conductive strips 604 are supplied with a current from the power control circuitry 526 in a desired sequence determined by the controller 502 (FIG. 5) to provide a wavelike movement of heat across the transparent cover 602 in one of the directions indicated by arrow 608. For example, a current may be supplied in sequence to conductive strips 612, 614, 616, 618, etc. by the power control circuitry 526 in FIG. 5. Current through each of the conductive strips 604 generates a resistive heat. Therefore, each of the conductive strips 604 comprises a microheater embedded within the display device 600. These microheaters are compact, easy to fabricate, contain no moving parts, and are easily integrated into an integrated circuit.

Although the display device 600 including the plurality of conductive strips 604 is the preferred embodiment, other embodiments are visualized. For example, a single conductor (not shown) tapered from one periphery to another would provide an increase of heat across the transparent cover 602 that would cause the contaminants 624 to migrate to a periphery.

During use of the display device 600, contaminants 624 (commonly referred to as smudges) from, for example, dust and oils from the user's touch, accumulate on the viewing surface 601 as shown in FIG. 6. These contaminants 624 impede the ability of the user to view the information presented through the transparent cover 602. Contaminants 624 comprising a liquid tend to form a droplet in order to reach its lowest energy configuration. Surface energy equals γ-Tγ/dT, where γ is the free surface energy. Surface tension of a liquid declines as the temperature increases due to thermal excitation. Therefore, as the temperature increases and the surface tension declines, the contaminant 624 will move towards the lower temperature. This is illustrated in FIG. 8 wherein the contaminant 624 has moved to the periphery 612 of the viewing surface 610 and away from the area viewed by the user in a manner dictated by the surface energy differences created by layer 607.

Optionally, a vibration device 622 may be attached so as to vibrate the transparent cover 602. The vibration device 622 may comprise, for example, a piezo electric transducer, and may comprise a haptic element that is otherwise used in an electronic device to provide information to the user, including for example, feedback relating to key activation. The vibration device 622 may be coupled to the controller 520 within the electronic device 510 for selective activation.

The activation of the optional vibration device 622 may be accomplished routinely during operation of the electronic device or as selected by the user. Activation of the vibration device 622 causes the transparent cover 602 to vibrate. This motion of the transparent cover 602 causes the contaminants 624 to more readily migrate in response to the application of voltages to the conductive strips 604 by helping to overcome any pinning effects, if present.

Once the contaminants 624 have migrated to the periphery of the transparent cover 602, the contaminants 624 may be hidden or eliminated by removal from the transparent cover 602. For example, a housing of the electronic device in which the electronic display is positioned, may extend over the periphery to cover or hide the contaminants 624 that have migrated across the transparent cover 602. Another embodiment may include an additional vibration device (not shown), whose movement would eject the smudges 624 from the transparent cover 602.

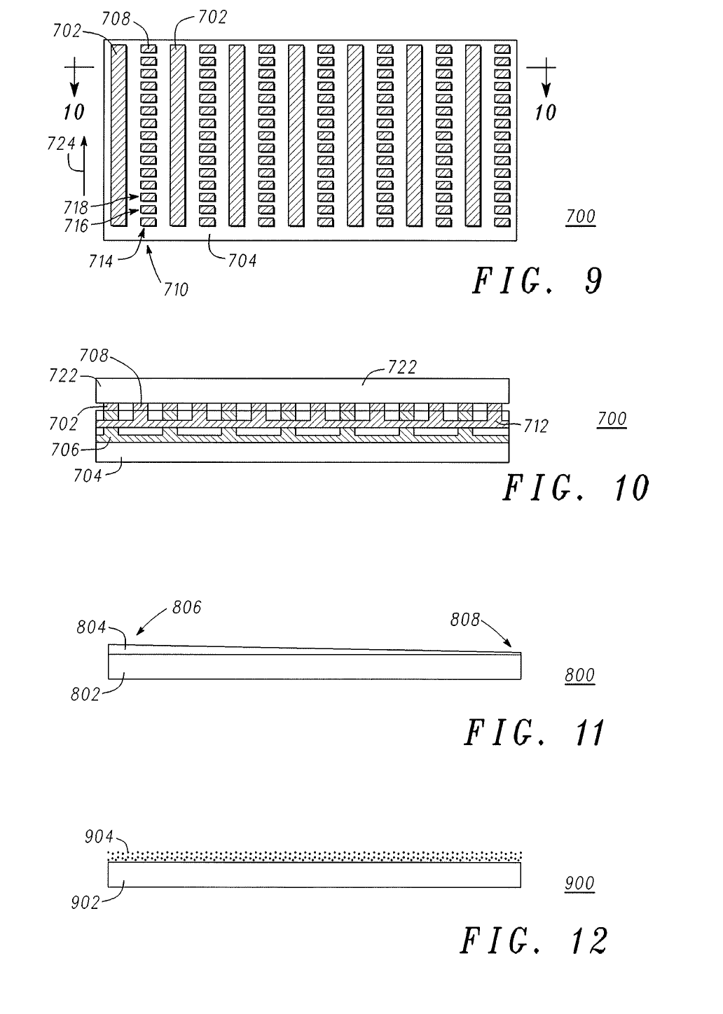

Referring to FIGS. 9 and 10 and in accordance with a second exemplary embodiment comprising electrical potential gradients, a display device 700 includes a plurality of conductor strips 702 formed on the substrate 704 and interconnected by conductors 706 lithographically formed within the substrate 704. A plurality of conductive islands 708 are formed in a column 710 between each pair of the conductive strips 702 and are interconnected by conductors 712 in rows, e.g., rows 714, 716, 718, etc. A transparent cover 722 may be formed over the conductor strips 702 and conductive islands 708. An electrically insulative anti-smudge or other functional film may be formed over cover 722. Each of the rows 714, 716, 718 are addressable in sequence by applying a voltage thereto, creating an electric field between that particular row in which the voltage is applied and the conductor strips in which a low potential, e.g., ground is applied. As the voltage is sequenced from one row, e.g., row 714, to another, e.g., row 716, the electric field created moves across the transparent cover 722 in the direction indicated by the arrow 724.

This potential “wave” moving across the surface can generate movement. When a conductive liquid is placed between two electrodes, an applied potential causes a layer of charge to build up at the interface. The applied potential (V) causes change in the interfacial energy (γ_{SL}) and can be described by the equation γ_{SL,V}=γ_{SL,0}−(εV²)/(2d). Not only does this mean that there will be a change in the contact angle as governed by Young's equation, but it also means that an imbalance of forces can be generated if the applied potential is not distributed uniformly over the droplet. This imbalance in turn can be sufficient to generate movement.

Referring to FIG. 11 and in accordance with a third exemplary embodiment comprising surface wettability gradients, a display device 800 includes a thin layer 804 formed on the substrate 802. The layer 804 comprises a chemically functionalized layer formed by chemically reacting appropriate materials in a diffusion limited manner from the end 806 of the substrate, thereby making the degree of functionalization on the substrate 802 higher at the end 806 and lower on the other end 808. Another method of forming the tapered layer 804 would be to immerse the substrate at an appropriate rate in a liquid containing the reactant, with the end 806 being immersed first. Since the end 806 is immersed in the liquid longer, the layer 804 will have a higher degree of functionalization at that end 806 than the other end 808. Alternatively, layer 804 could comprise a physical gradient with end 806 possessing a higher degree of roughness than end 808.

These surface wettability gradients induce motion by creating an imbalance in the interfacial energy along the solid/liquid interface. The interfacial energy is dependent upon the degree of attraction of the droplet to the surface via polar, van der waal, or other forces. Different types of surfaces and/or chemical groups have differing degrees of attraction. By functionalizing a surface with chemicals exposing dissimilar chemical groups, areas having dissimilar degrees of attraction can be generated. If a droplet overlaps areas having differing degrees of attraction, it will be pulled towards the area having a higher surface energy in order to lower overall interfacial energy. The physical gradient works in a similar manner although the differing levels of attraction and resulting imbalance of forces are dictated by the differences in the physical areas available for interaction rather than differing attractive forces for areas of similar area.

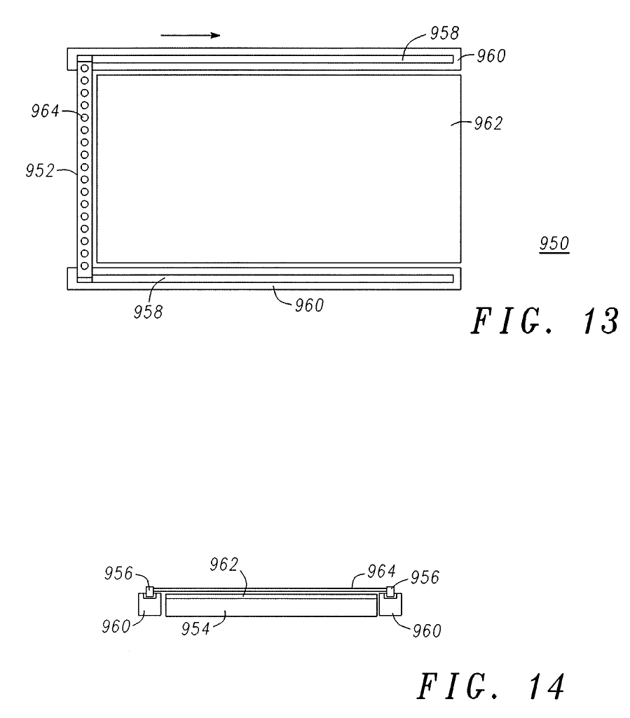

Referring to FIG. 12 and in accordance with a fourth exemplary embodiment comprising a photosensitive layer, a display device 900 comprises a thin layer 904 of a photosensitive material such as azobenzene terminated calyx(4)resorcinarenes which is formed over the substrate 902. Such molecules can be isomerized in both trans- and cis-configurations. Moreover, transfer between states can be accomplished through photoactivation. Hence, movement can be generated in a manner similar to a surface wettability gradient. Rather than having a static chemically functionalized layer; however, the chemical groups exposed at the surface can changed in a wave-like manner by sweeping light of the appropriate wavelength across the surface. While this does require an external light source, it can potentially generate a much stronger gradient and such a source can possibly be the display itself.

Referring to FIGS. 13 and 14, further exemplary embodiments comprise an apparatus 950 in which the gradients may be created within the arm 952 or by moving an aim 952 across the display surface 954. The arm 952 may comprise a wire, as shown in FIG. 14, to create a thermal or electrical gradient, or it may comprise a holder, as shown in FIG. 15, for positioning a plurality or light sources 964, e.g., light emitting diodes, to create an optical gradient. The arm 952 is attached to arm supports 956 on two sides of the display surface 954 and on the substrate 960. On command from the controller 520, the arm supports 956 moves within grooves 958 formed in the substrate 960, taking the arm 952 across the display surface 954. Motion may be imparted to the arm 952 by a system of pulleys or gears (not shown). The arm 952 may move in one direction in response to a command, and in the reverse direction in response to the next command. The arm 952 may touch the display surface 954 or it may be positioned a small distance from the display surface 954. Additionally, the arm 952 may be mechanically moved by hand overriding the controller command to make a manual swipe over the display surface 954.

In the case of creating thermal gradients, current would be provided through the arm 952 providing heat. As the arm 952 moves across the display surface 954, a “wave” of heat moves across the display surface 954 causing smudges to migrate across the display surface 954. This exemplary embodiment would negate the need for the plurality of conductive strips as shown in FIGS. 6 and 7.

In the case of creating electrical gradients, a transparent ground plane 962 would be formed in the display or on the display surface 954. As the aim 952 moves across the display surface 954, current is passed through the arm 952 creating an electrical field between the arm 952 and the conductive plane 962, thereby creating an electric field wave across the display surface 954.

In the case of creating optical gradients, the arm 952 would be moved across the thin layer 904 of photosensitive material shown in FIG. 12. The optical sources 964 positioned within the arm 952 would be active upon instructions from the controller 520, creating a wave of light to activate the photosensitive material. Different types of light sources 964 may be included. For example, the LEDs could emit the light from Infra-red to visibile to the ultra-violet regime of the spectrum. the sources of light 964 may be varied to maximize the effect of cleaning the surface by combination of multiple wavelength emitting sources or use of one specific wavelength.

It should be noted that combinations of these embodiments can also exist. For instance, the optional functional layer of the first embodiment could be a surface wettability gradient as described in the third embodiment. It could also be a layer which can be switched in a controlled manner similar to what is described in the fourth embodiment like poly(N-isopropyl acrylamide-co-acrylic acid) films which show reversible switching between surface energy states based on temperature. Hence, forces could be generated by both thermal and thermally activated chemical gradients working together simultaneously. The common element in all cases, however, is an imbalance of the interfacial energy along the interface of the droplet or smudge and the surface.

It will be appreciated that the vibration device 622 may optionally used with any of the exemplary embodiments such as those described herein.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. An electronic device comprising:
a housing;
a display device positioned within the housing and comprising a transparent cover having a surface viewable outside of the housing and susceptible to receiving a smudge, the transparent cover including elements for creating gradients that cause the smudge to migrate across the surface; and
electronic circuitry to present information through the transparent cover.

2. The electronic device of claim 1 wherein the gradients comprises one of thermal, electrical, optical, or surface wettability gradients.

3. The electronic device of claim 1 wherein the gradients comprise a plurality of conductive strips formed on the transparent cover, and the electronic device comprises circuitry for sequentially addressing the plurality of conductive strips by conducting a current therethrough.

4. The electronic device of claim 1 wherein the gradient comprises:
a plurality of conductive strips formed on the transparent cover;
a plurality of conductive islands formed in an array of columns and rows on the transparent cover, wherein each of the columns are formed between adjacent conductive strips; and
wherein the electronic device comprises circuitry for sequentially addressing the rows of conductive strips by conducting a current therethrough.

5. The electronic device of claim 1 wherein the gradient comprises a photosensitive material having chemical groups exposed at the surface capable of being changed in a wave-like manner by sweeping light of the appropriate wavelength across the surface.

6. The electronic device of claim 1 wherein the gradient comprises a chemically functionalized layer.

7. The electronic device of claim 1 further comprising an arm capable of being moved across the surface for creating the gradients.

8. The electronic device of claim 1 further comprising at least one vibration device coupled to the transparent cover.

9. An electronic device comprising:
a display device comprising a transparent cover having a viewable surface susceptible to receiving contaminants, the transparent cover including gradients that cause contaminants to migrate across the surface; and
electronic circuitry to present information through the transparent cover.

10. The electronic device of claim 9 wherein the gradients comprises one of thermal, electrical, optical, or surface wettability gradients.

11. The electronic device of claim 9 wherein the gradients comprise a plurality of conductive strips formed on the transparent cover, and the electronic device comprises circuitry for sequentially addressing the plurality of conductive strips by conducting a current therethrough.

12. The electronic device of claim 9 wherein the gradient comprises:
a plurality of conductive strips formed on the transparent cover;
a plurality of conductive islands formed in an array of columns and rows on the transparent cover, wherein each of the columns are formed between adjacent conductive strips; and
wherein the electronic device comprises circuitry for sequentially addressing the rows of conductive strips by conducting a current therethrough.

13. The electronic device of claim 9 wherein the gradient comprises a photosensitive material having chemical groups exposed at the surface capable of being changed in a wave-like manner by sweeping light of the appropriate wavelength across the surface.

14. The electronic device of claim 9 wherein the gradient comprises a chemically functionalized layer.

15. A method of moving contaminants from a viewing area of a transparent surface of an electronic device display, comprising causing the contaminants to migrate across the surface by a plurality of gradients defined by the display.

16. The electronic device of claim 15 wherein the gradients comprises one of thermal, electrical, optical, or surface wettability gradients.

17. The electronic device of claim 15 wherein the gradients comprise a plurality of conductive strips formed contiguous to the transparent cover, the method further comprising sequentially addressing the plurality of conductive strips by conducting a current therethrough.

18. The electronic device of claim 15 wherein the gradients comprise a plurality of conductive islands formed in an array of columns and rows contiguous to the transparent cover wherein each column is formed between adjacent conductive strips, the method further comprising sequentially addressing the rows of conductive islands by conducting current therethrough.

19. The electronic device of claim 15 wherein the gradients comprise a photosensitive material having chemical groups exposed at the surface, the method further comprising sweeping light across the surface.

20. The electronic device of claim 15 wherein the gradients comprises a chemically functionalized layer.

21. The electronic device of claim 15 wherein the gradients are created by moving an arm across the surface, the arm comprising one of a wire for carrying a current or a holder for positioning a plurality of light sources therein.
